(19) United States
(12) Patent Application Publication
(10) Pub. No.: US 2025/0062276 A1
(43) Pub. Date: Feb. 20, 2025

(54) METHOD FOR DIPPING ADHESIVE MATERIAL

(71) Applicant: ELECTRONICS AND TELECOMMUNICATIONS RESEARCH INSTITUTE, Daejeon (KR)

(72) Inventors: Jung Ho Shin, Daejeon (KR); Chan Mi Lee, Daejeon (KR); Ji Ho Joo, Daejeon (KR); Gwang Mun Choi, Daejeon (KR); Yong Sung Eom, Daejeon (KR); Kwang Seong Choi, Daejeon (KR); Seok Hwan Moon, Daejeon (KR); Jin Hyuk Oh, Daejeon (KR); Ho Gyeong Yun, Daejeon (KR); Ki Seok Jang, Daejeon (KR)

(21) Appl. No.: 18/807,628

(22) Filed: Aug. 16, 2024

(30) Foreign Application Priority Data
Aug. 16, 2023 (KR) 10-2023-0107229
Dec. 6, 2023 (KR) 10-2023-0175949

(51) Int. Cl. H01L 23/00

(52) U.S. Cl. CPC H01L 24/83; H01L 2224/83192; H01L 2224/83801; H01L 2224/8385

(57) ABSTRACT

The present invention relates to a method for dipping an adhesive material, and the method for dipping an adhesive material includes dipping an adhesive material onto a first dipping stamp, transferring the adhesive material, which is dipped onto the first dipping stamp, to a target substrate, and transferring a device to the target substrate, to which the adhesive material is transferred.

### CROSS-REFERENCE TO RELATED APPLICATION

The present application claims priority to and the benefit of Korean Patent Application No. 10-2023-0107229, filed on Aug. 16, 2023, and Korean Patent Application No. 10-2023-0175949, filed on Dec. 6, 2023, in the Korean Intellectual Property Office, the entire disclosures of which are incorporated herein by reference.

### BACKGROUND

### 1. Field of the Invention

The present invention relates to a method for dipping an adhesive material, which enables the adhesive material to be selectively applied on a target substrate.

### 2. Discussion of Related Art

Recently, due to the difficulties in miniaturizing semiconductor devices in accordance with Moore's Law, there are limits to improving an integration density at a front-end processing stage of semiconductor manufacturing.

Accordingly, semiconductor companies and research institutes are focusing on the miniaturization of solder bump pitch at a packaging stage. In addition, in the case of micro light-emitting diode (micro-LED) displays, which are currently being evaluated as next-generation technology in the display market, transfer/bonding and repair processes are being developed to highly integrate LED chips ranging in size from as large as 50 μm to as small as 10 μm into several hundreds to thousands of pixels per inch (ppi). Accordingly, the demand for the selective application of an adhesive material for bonding between devices and solder at a resolution level of tens of μm or less is rapidly increasing.

A conventional adhesive material coating method can be classified according to the type of material. Film-type materials are applied using thermal compression or vacuum lamination, while paste-type materials are applied using dispensing, screen printing, spin coating, bar coating, and ink-jet printing. Among them, the lamination, the spin coating, and the bar coating are batch coating methods, making it impossible to selectively apply the material only to a specific region. The screen printing and the dispensing allow the selective application of the material, but the achievable resolution exceeds 100 μm, making them unsuitable for bonding devices smaller than several tens of μm. The ink-jet printing is effective for applying an adhesive material at a resolution of several tens of μm or less, but has limitations for mass production applications due to its very slow processing speed.

### SUMMARY OF THE INVENTION

The present invention is directed to providing a method for dipping an adhesive material, which enables the adhesive material to be selectively applied to a specific region within several tens of μm on a target substrate.

According to an aspect of the present invention, there is provided a method for dipping an adhesive material, the method including dipping an adhesive material onto a first dipping stamp, transferring the adhesive material, which is dipped onto the first dipping stamp, to a target substrate, and transferring a device to the target substrate, to which the adhesive material is transferred.

In the present invention, the first dipping stamp may include a base part, and a concave-convex part provided on the base part, wherein the concave-convex part may include one or more protrusions.

In the present invention, the adhesive material may be in the form of a film or paste and may be made of at least one of a curable resin, a reducing agent, a thermoplastic resin, a curing agent, and a solder.

In the present invention, the dipping of the adhesive material may include bringing the first dipping stamp into contact with the adhesive material in a state in which the adhesive material is heated, and then pressing the first dipping stamp, cooling the adhesive material and then separating the first dipping stamp from the adhesive material, and dipping the adhesive material onto protrusions of the first dipping stamp.

In the present invention, a shape and volume of the adhesive material dipped onto the first dipping stamp may be determined by at least one of a surface state, a heating temperature, and an applied pressure of the protrusions of the first dipping stamp and the adhesive material.

The method may further include, after the dipping of the adhesive material onto the protrusions of the first dipping stamp, forming the separated adhesive material into a flat film or paste by heating or blading.

In the present invention, the target substrate may include a substrate base part, and one or more device bonding parts disposed on an upper surface of the substrate base part.

In the present invention, the transferring of the dipped adhesive material to the target substrate may include bringing protrusions of the first dipping stamp, on which the adhesive material is dipped, into contact with the corresponding device bonding parts of the target substrate, respectively, in a state in which the target substrate is heated, cooling the dipped adhesive material and the target substrate and then separating the first dipping stamp from the target substrate, and transferring the dipped adhesive material to the device bonding parts.

The method may further include, before the bringing of the protrusions of the first dipping stamp, on which the adhesive material is dipped, into contact with the corresponding device bonding parts of the target substrate, respectively, performing a surface treatment process on the target substrate.

In the present invention, the transferring of the device to the target substrate may include transferring the device to the device bonding part of the target substrate, on which the adhesive material is dipped, using a transfer process, and electrically connecting the device to the substrate base part of the target substrate by activating the dipped adhesive material to electrically and physically connect the device to the device bonding part.

According to another aspect of the present invention, there is provided a method for dipping an adhesive material, the method including dipping an adhesive material onto a second dipping stamp having one or more devices provided thereon, and transferring and bonding the one or more devices to a target substrate through the adhesive material dipped onto the second dipping stamp.

In the present invention, the second dipping stamp may include an interposer, and one or more devices provided on the interposer, wherein the interposer may be a substrate formed of at least one of Si, glass, quartz, and a polymer film, with an adhesive layer formed in a film form or as a pattern array.

In the present invention, the adhesive material may be in the form of a film or paste and may be made of at least one of a curable resin, a reducing agent, a thermoplastic resin, a curing agent, and a solder.

In the present invention, the dipping of the adhesive material may include bringing the second dipping stamp into contact with the adhesive material in a state in which the adhesive material is heated, and then pressing the second dipping stamp, cooling the adhesive material and then separating the second dipping stamp from the adhesive material, and dipping the adhesive material onto the devices of the second dipping stamp.

In the present invention, a shape and volume of the adhesive material dipped onto the second dipping stamp may be determined by at least one of a surface state, a heating temperature, and an applied pressure of the devices of the second dipping stamp and the adhesive material.

The method may further include, after the dipping of the adhesive material onto the devices of the second dipping stamp, forming the separated adhesive material into a flat film or paste by heating or blading.

In the present invention, the target substrate may include a substrate base part, and one or more device bonding parts disposed on an upper surface of the substrate base part.

In the present invention, the transferring and bonding of the one or more devices to the target substrate may include bringing the devices of the second dipping stamp, on which the adhesive material is dipped, into contact with the corresponding device bonding parts of the target substrate, respectively, and then activating the dipped adhesive material to form electrical and physical connections between the devices and the device bonding parts, and transferring and bonding the devices to the target substrate by separating an interposer of the second dipping stamp from the devices.

In the present invention, in the forming of the electrical and physical connections between the devices and the device bonding parts, the second dipping stamp may be moved toward the target substrate and brought into contact with the target substrate so that the devices, on which the adhesive material is dipped, are disposed on the corresponding device bonding parts of the target substrate, respectively, an external force may be applied to activate the dipped adhesive material, and the devices and the device bonding parts may be electrically and physically connected by the activated adhesive material.

The method may further include, before the bringing of the devices of the second dipping stamp, on which the adhesive material is dipped, into contact with the corresponding device bonding parts of the target substrate, respectively, performing a surface treatment process on the target substrate.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIGS. 1A and 1B are cross-sectional views for describing a dipping stamp according to one embodiment of the present invention;

FIGS. 2A, 2B, 2C, 2D, 2E, 2F, and 2G are a set of cross-sectional views for describing a method for dipping an adhesive material using a first dipping stamp according to one embodiment of the present invention;

FIGS. 3A, 3B, 3C, and 3D are a set of views illustrating experimental results obtained by actually performing the process illustrated in FIG. 2A to 2G;

FIG. 4 is a cross-sectional view for describing an interposer-based dipping stamp according to another embodiment of the present invention;

FIGS. 5A, 5B, 5C, 5D, 5E, and 5F are a set of cross-sectional views for describing a method for dipping an adhesive material using a second dipping stamp according to one embodiment of the present invention;

FIGS. 6A and 6B are graphs illustrating experimental results of viscosity changes over heating time for an underfill film, which is one of adhesive materials according to one embodiment of the present invention;

FIGS. 7A, 7B, 7C, 7D, and 7E are views for describing a tiling process according to one embodiment of the present invention;

FIGS. 8A, 8B, 8C, and 8D are views for describing a tiling process according to another embodiment of the present invention;

FIG. 9 is a flowchart for describing a method for dipping an adhesive material using the first dipping stamp according to one embodiment of the present invention; and

FIG. 10 is a flowchart for describing a method for dipping an adhesive material using the second dipping stamp according to one embodiment of the present invention.

### DETAILED DESCRIPTION OF EXEMPLARY EMBODIMENTS

Hereinafter, embodiments of a method for dipping an adhesive material according to one embodiment of the present invention will be described.

In this process, the thickness of lines or the size of elements illustrated in the drawings may be exaggerated for clarity and convenience of description. In addition, the terms described below are defined in consideration of the functions of the present invention, and these terms may be varied according to the intent of a user or an operator or a custom. Accordingly, the definitions of such terms should be given on the basis of the content throughout the specification.

Hereinafter, embodiments of the present invention will be described in detail with reference to the accompanying drawings so that those of ordinary skill in the art can easily implement them. However, the present invention may be implemented in various different forms and is not limited to the embodiments described below. In addition, parts irrelevant to the description will be omitted in the drawings in order to clearly explain embodiments of the present invention. Similar parts are denoted by similar reference numerals throughout this specification.

Throughout the specification, when a part is referred to as including a component, it means that the part may include other components as well without controlling the other components unless specifically stated otherwise.

The embodiments described herein may be implemented, for example, as a method or process, an apparatus, a software program, a data stream, or a signal. Even when the present invention is described only in the context of a single embodiment (e.g., a method), the features of the embodiment can be implemented in different forms (e.g., an apparatus or program). The apparatus may be implemented as appropriate hardware, software, firmware, or the like. The method may be implemented by an apparatus such as a processor that generally refers to processing devices, including a computer, a microprocessor, an integrated circuit, or a programmable logic device.

The present invention relates to a process of selectively applying an adhesive material to a specific region within several tens of μm on a desired substrate through dipping of the adhesive material using a stamp.

The present invention relates to a method for dipping an adhesive material, enabling the transfer/bonding and repair of semiconductors and display devices on a target substrate with a resolution of several tens of μm and a high processing speed of less than a few seconds.

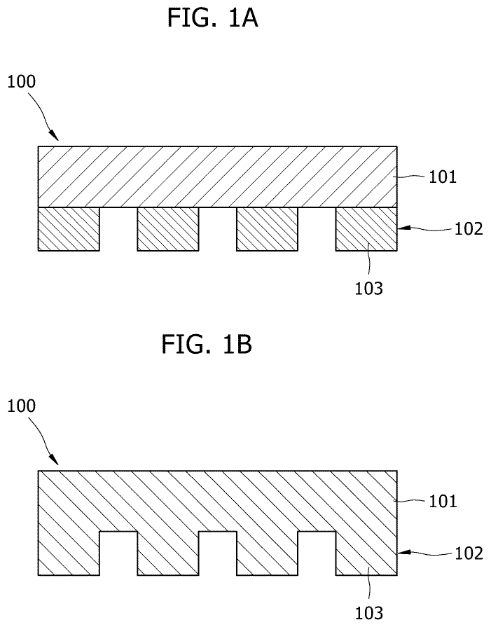

FIGS. 1A and 1B are cross-sectional views for describing a dipping stamp according to one embodiment of the present invention.

Referring to FIGS. 1A and 1B, a dipping stamp 100 according to one embodiment of the present invention may include a base part 101 and a concave-convex part 102.

The base part 101 may be Si, glass, quartz, or a polymer film, but the present invention is not limited thereto.

The concave-convex part 102 may be provided on a lower surface of the base part 101. However, it may be said that, when the dipping stamp 100 is turned upside down, the concave-convex part 102 is provided on an upper surface of the base part 101. The relative positional relationship between the base part 101 and the concave-convex part 102 can vary based on the arrangement of the dipping stamp 100.

The concave-convex part 102 may include at least one protrusion 103. A plurality of protrusions 103 may be disposed to be spaced apart from each other. An empty space between two adjacent protrusions 103 may be referred to as a type of “depression.” Accordingly, it can be seen that the concave-convex part 102 has a structure in which the protrusions 103 and depressions are alternately disposed.

The protrusion 103 may have a width or diameter of several hundred μm or less.

The protrusion 103 may be formed of one of the materials including a photosensitizer, a photo-sensitive organic material, a metal, a ceramic, and a polymer compound.

The protrusion 103 may be present on the base part 101 as one protrusion or a plurality of protrusions.

The base part 101 and the concave-convex part 102 may be made of different materials as illustrated in FIG. 1A, but may also be made of the same material as illustrated FIG. 1B.

When the base part 101 and the concave-convex part 102 are made of the same material, the dipping stamp 100 may be formed by dry/wet etching a portion of the base part 101 into one or more protrusions 103, so that both the base part 101 and the protrusions 103 are made of the same material. In this case, the base part 101 may be Si, glass, quartz, or a polymer film, but the present invention is not limited thereto.

The dipping stamp 100, which is configured as described above, has the protrusions 103 formed according to the arrangement of a device array to be bonded onto a target substrate 400, and enables an adhesive material 200 to be selectively applied to only a desired position on the target substrate 400 with a resolution of several tens of μm. That is, the dipping stamp 100 is fabricated according to the shape and position of a device to be bonded onto the target substrate 400, allowing an adhesive material to be selectively applied in a single dipping and transferring process using the dipping stamp 100.

Hereinafter, for convenience of description, the dipping stamp 100 illustrated in FIG. 1 will be referred to as a first dipping stamp 100.

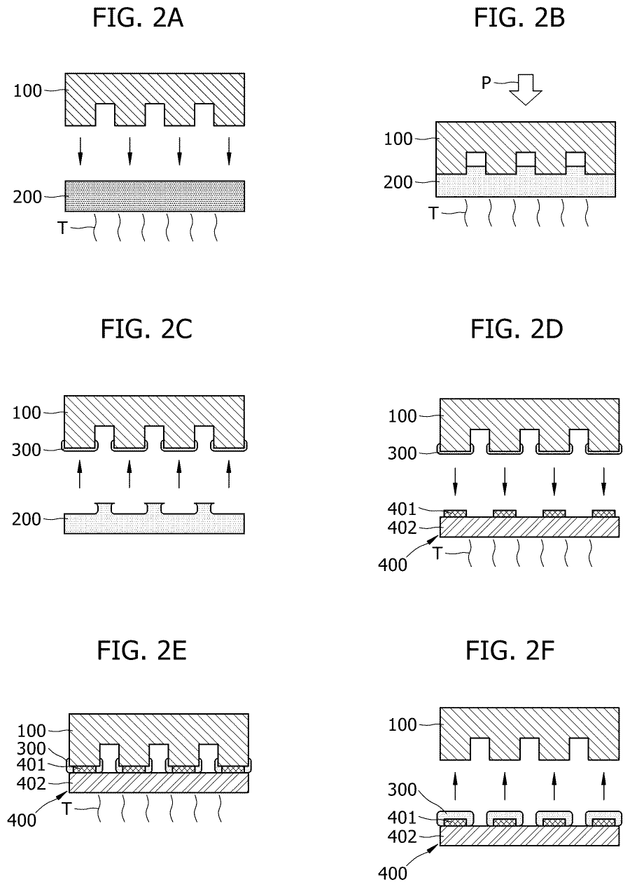

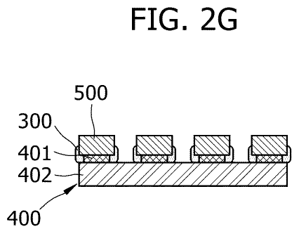

FIGS. 2A to 2G are a set of cross-sectional views for describing a method for dipping an adhesive material using the first dipping stamp according to one embodiment of the present invention.

First, as shown in FIG. 2A, in a state in which the adhesive material 200 is heated to a certain temperature T, the first dipping stamp 100 may be moved closer to the adhesive material 200. That is, in a state in which the adhesive material 200 is heated to the certain temperature T to reduce a viscosity thereof so that the adhesive material 200 can be dipped onto the first dipping stamp 100, the dipping stamp 100 may be moved closer to the adhesive material 200. Here, the adhesive material 200 may be in the form of a film or paste and may be made of one or more of a curable resin, a reducing agent, a thermoplastic resin, a curing agent, and a solder.

The adhesive material 200 may be heated using various heating processes, such as halogen lamp heating, infrared heating, resistance heating, arc heating, induction heating, dielectric heating, electron beam heating, and the like. As an example, the infrared heating may include a process of irradiating an infrared radiation (IR) laser. At this time, the adhesive material 200 may be heated to, for example, 80° C. to 100° C.

Next, as shown in FIG. 2B, the first dipping stamp 100 may be brought into contact with the adhesive material 200, and then pressed with a certain pressure P. At this time, the adhesive material 200 may be in a heated state.

Next, as shown in FIG. 2C, the adhesive material 200 may be cooled to room temperature, and then, the first dipping stamp 100 may be separated from the adhesive material 200. At this time, the adhesive material 200 may be cooled using various cooling sources such as nitrogen or coolant liquid.

When the adhesive material 200 is cooled and the first dipping stamp 100 is separated therefrom, an adhesive material 300 may be dipped onto the protrusions 103 of the dipping stamp 100. At this time, a shape and volume V of the adhesive material 300 dipped onto the first dipping stamp 100 may be determined by at least one of a surface state, a temperature T, and a pressure P of the protrusion 103 of the first dipping stamp 100 and the adhesive material 200. That is, the amount, shape, or the like of the adhesive material 300 dipped onto the protrusion 103 may vary based on at least one of the surface state, the temperature T, and the pressure P of the protrusion 103 of the dipping stamp 100 and the adhesive material 200.

After the dipping of the adhesive material 200 is completed, the viscosity of the adhesive material 200 is lowered through heating to remove dipped marks in the adhesive material 200, thereby forming the adhesive material 200 into a flat film or paste, which is the same as it was before dipping. In addition, by blading the separated adhesive material 200, the adhesive material 200 may be reformed into a flat film or paste. By heating or blading the separated adhesive material 200 as described above, the adhesive material 200 may be reformed into a flat film or paste.

Next, as shown in FIG. 2D, in a state in which the target substrate 400 is heated, the first dipping stamp 100 including the dipped adhesive material 300 is aligned with the target substrate 400, and then the first dipping stamp 100 may be moved closer to the target substrate 400.

That is, in a state in which the target substrate 400 is heated through a heating process, the first dipping stamp 100 may be moved toward the target substrate 400 so that the protrusions 103, on which the adhesive material 300 is dipped, are correspondingly positioned on device bonding parts 401 of the target substrate 400, respectively. At this time, the target substrate 400 may be heated using various heating processes, such as halogen lamp heating, infrared heating, resistance heating, arc heating, induction heating, dielectric heating, electron beam heating, and the like. As an example, the infrared heating may include a process of irradiating an IR laser. At this time, the target substrate 400 may be heated to, for example, 80° C. to 100° C.

The target substrate 400 may include the device bonding parts 401 and a substrate base part 402.

Each of the device bonding parts 401 may be a thin-film metal including one or more of chromium (Cr), titanium (Ti), molybdenum (Mo), aluminum (Al), gold (Au), copper (Cu), nickel (Ni), or may include a solder composed of an alloy selected from metals or non-metals such as tin (Sn), silver (Ag), copper (Cu), lead (Pb), bismuth (Bi), indium (In), cadmium (Cd), antimony (Sb), gallium (Ga), arsenic (As), germanium (Ge), zinc (Zn), aluminum (Al), gold (Au), silicon (Si), nickel (Ni), phosphorus (P), and a combination thereof.

The substrate base part 402 may be one of a backplane, a printed circuit board (PCB), or an integrated circuit, but the present invention is not limited thereto. For example, when the substrate base part 402 includes a backplane, the backplane may be one of an oxide thin-film transistor (TFT) backplane, a complementary metal-oxide semiconductor (CMOS) backplane, a low-temperature polysilicon (LTPS) backplane, and an a-Si backplane, but the present invention is not limited thereto.

In order to facilitate the application of the dipped adhesive material 300 onto the target substrate 400, a surface treatment process including oxygen plasma and ultraviolet ray treatment may be performed on the target substrate 400 before implementing FIG. 2D. When the surface treatment process is performed on the target substrate 400, the adhesive material 300 may be applied more effectively on the target substrate 400.

Next, as shown in FIG. 2E, the first dipping stamp 100 may be brought into contact with the target substrate 400. At this time, the target substrate 400 may be in a heated state. Accordingly, when the dipping stamp 100 is brought into contact with (attached to) the heated target substrate 400, the adhesive material 300 dipped onto the dipping stamp 100 may flow down onto the target substrate 400 and may be dipped (applied).

Next, as shown in FIG. 2F, when the dipped adhesive material 300 and the target substrate 400 are cooled to room temperature and then the first dipping stamp 100 is separated from the target substrate 400, the dipped adhesive material 300 may be transferred (dipped or applied) to the device bonding parts 401. At this time, the adhesive material 300 and the target substrate 400 may be cooled using various cooling sources such as nitrogen or coolant liquid.

In some embodiments of the present invention, the process of FIGS. 2A-2F may be performed without heating to a certain temperature T, depending on the properties of the adhesive material (e.g., viscosity).

Next, as shown in FIG. 2G, devices 500 may be transferred to the target substrate 400, on which the adhesive material 300 has been dipped, using various transfer processes. For example, transfer processes such as laser-induced forward transfer, electrostatic transfer, fluidic-based assembly transfer, elastomer stamp transfer, roll-to-roll (R2R) transfer, vacuum suction force-based transfer, electromagnetic transfer, and the like may be used to transfer the devices 500 to the target substrate 400. Here, the devices 500 may be one of MLCCs, CMOS chips, ASICs, HBMs, SoCs, micro LEDs, and mini LEDs, but the present invention is not limited thereto.

When one or more external forces, such as heat, laser, and pressure, are applied, the adhesive material 300 dipped onto the target substrate 400 is activated, and the devices 500 transferred to the target substrate 400 may form electrical and physical connections with the device bonding parts 401 through the activated adhesive material 300. Then, the devices 500 may be electrically connected to the substrate base part 402 of the target substrate 400.

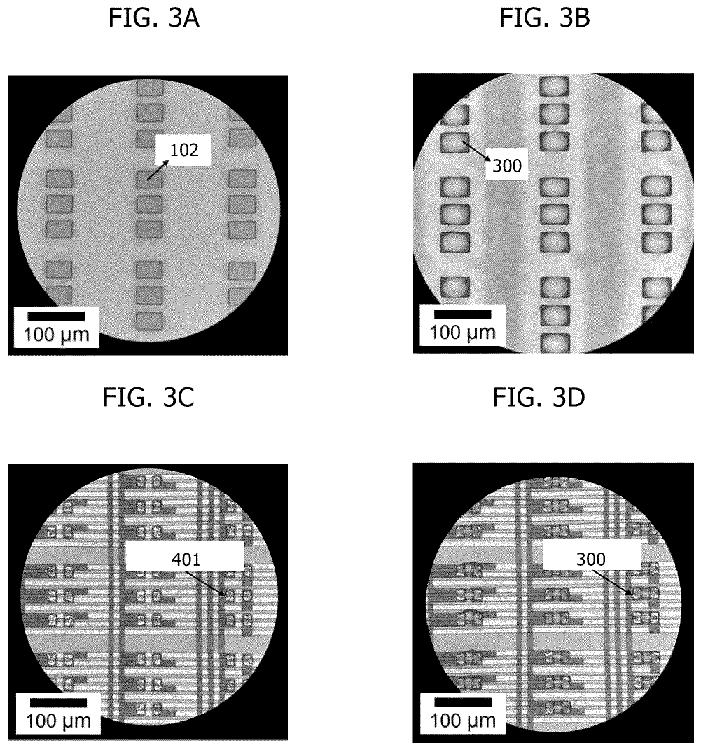

FIGS. 3A to 3D are a set of views illustrating experimental results obtained by actually performing the process illustrated in FIG. 2A to 2G.

FIG. 3A is an enlarged bottom view of the first dipping stamp 100 manufactured using a Si substrate and a photosensitive organic material. This illustrates the first dipping stamp 100 formed by patterning the photosensitive organic material coated on the Si substrate through a photolithography process to form the protrusions 103 for applying an adhesive material.

FIG. 3B is a bottom view for describing the adhesive material 300 dipped onto the first dipping stamp 100 manufactured in FIG. 3A. Referring to FIG. 3B, it can be seen that the adhesive material 300 has been dipped onto the protrusion 103 of the dipping stamp 100.

FIG. 3C is an enlarged bottom view of the target substrate 400 including the device bonding parts 401, and FIG. 3D is an enlarged bottom view for describing the adhesive material 300 applied only on the device bonding parts 401 of the target substrate 400 of FIG. 3C. It can be seen that when the dipping stamp 100 of FIG. 3B is brought into contact with the target substrate 400 after preparing the target substrate 400 including the device bonding parts 401 as shown in FIG. 3C, the adhesive material 300 dipped onto the dipping stamp 100 is selectively applied only to the device bonding parts 401 of the target substrate 400, as shown in FIG. 3D.

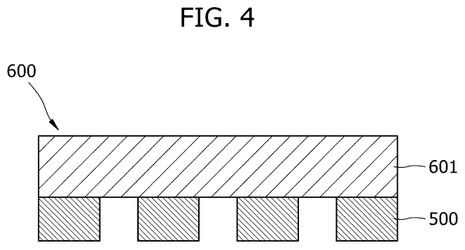

FIG. 4 is a cross-sectional view for describing an interposer-based dipping stamp according to another embodiment of the present invention.

Referring to FIG. 4, an interposer-based dipping stamp 600 according to another embodiment of the present invention may include an interposer 601 and one or more devices 500.

The interposer 601 may be a type of transfer substrate that rearranges the devices 500 formed on a mother substrate into a designed array of the devices 500 on the actual target substrate 400. The interposer 601 may be a substrate formed of Si, glass, quartz, or a polymer film, with an adhesive layer formed in a film form or as a pattern array with a width of several hundred μm or less.

An adhesive layer constituting the interposer 601 may be one of polydimethylsiloxane (PDMS) and a UV curing film, but the present invention is not limited thereto.

The devices 500 may be provided on a lower surface of the interposer 601. However, it may be said that, when the interposer-based dipping stamp 600 is turned upside down, the devices 500 are provided on an upper surface of the interposer 601. The relative positional relationship between the interposer 601 and the devices 500 can vary based on the arrangement of the interposer-based dipping stamp 600.

A plurality of devices 500 may be disposed to be spaced apart from each other.

The devices 500 may be one of MLCCs, CMOS chips, ASICs, HBMs, SoCs, micro LEDs, and mini LEDs, but the present invention is not limited thereto.

Hereinafter, for convenience of description, the interposer-based dipping stamp 600 illustrated in FIG. 4 will be referred to as a second dipping stamp 600.

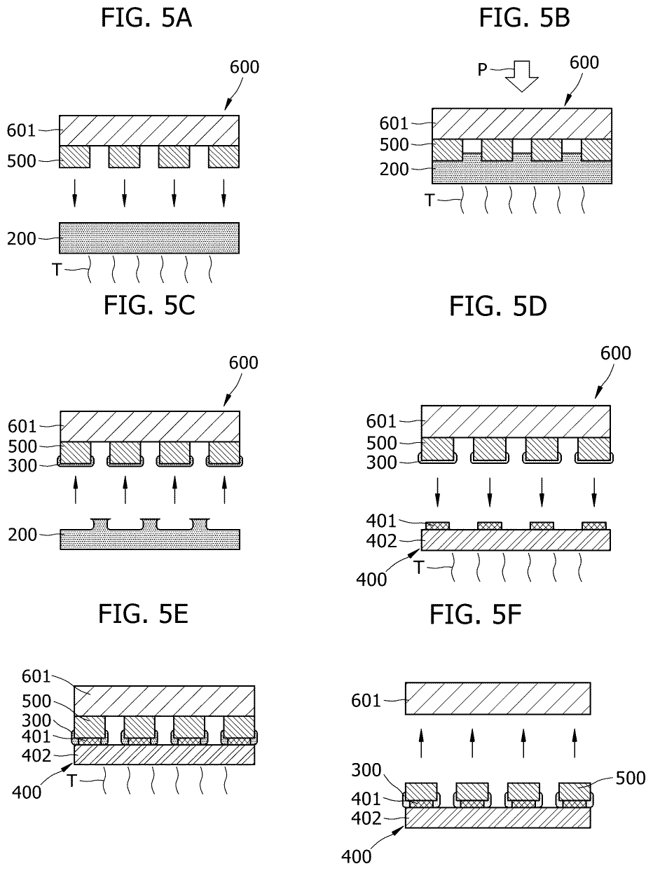

FIGS. 5A to 5F are a set of cross-sectional views for describing a method for dipping an adhesive material using a second dipping stamp according to one embodiment of the present invention.

First, as shown in FIG. 5A, in a state in which the adhesive material 200 is heated to a certain temperature T, the second dipping stamp 600 may be moved closer to the adhesive material 200. That is, in a state in which the adhesive material 200 is heated to the temperature T to reduce a viscosity thereof so that the adhesive material 200 can be dipped onto the second dipping stamp 600, the second dipping stamp 600 may be moved closer to the adhesive material 200. Here, the adhesive material 200 may be in the form of a film or paste and may be made of one or more of a curable resin, a reducing agent, a thermoplastic resin, a curing agent, and a solder.

The adhesive material 200 may be heated using various heating processes, such as halogen lamp heating, infrared heating, resistance heating, arc heating, induction heating, dielectric heating, electron beam heating, and the like. As an example, the infrared heating may include a process of irradiating an IR laser. At this time, the adhesive material 200 may be heated to, for example, 80° C. to 100° C.

Next, as shown in FIG. 5B, the second dipping stamp 600 may be brought into contact with the adhesive material 200, and then pressed with a certain pressure P. At this time, the adhesive material 200 may be in a heated state.

Next, as shown in FIG. 5C, the adhesive material 200 may be cooled to room temperature, and then, the second dipping stamp 600 may be separated from the adhesive material 200. At this time, the adhesive material 200 may be cooled using various cooling sources such as nitrogen or coolant liquid.

When the adhesive material 200 is cooled and the second dipping stamp 600 is separated therefrom, the adhesive material 300 may be dipped onto the devices 500 of the second dipping stamp 600. At this time, a shape and volume V of the adhesive material 300 dipped onto the second dipping stamp 600 may be determined by at least one of a surface state, a temperature T, and a pressure P of the device 500 of the second dipping stamp 600 and the adhesive material 200. That is, the amount, shape, or the like of the adhesive material 300 dipped onto the device 500 may vary based on at least one of the surface state, the temperature T, and the pressure P of the device 500 of the second dipping stamp 600 and adhesive material 200.

After the dipping of the adhesive material 200 is completed, the viscosity of the adhesive material 200 is lowered through heating to remove dipped marks in the adhesive material 200, thereby forming the adhesive material 200 into a flat film or paste, which is the same as it was before dipping. In addition, by blading the separated adhesive material 200, the adhesive material 200 may be reformed into a flat film or paste. By heating or blading the separated adhesive material 200 as described above, the adhesive material 200 may be reformed into a flat film or paste.

Next, as shown in FIG. 5D, in a state in which the target substrate 400 is heated, the second dipping stamp 600 including the dipped adhesive material 300 is aligned with the target substrate 400, and then the second dipping stamp 600 may be moved closer to the target substrate 400.

That is, in a state in which the target substrate 400 is heated through a heating process, the second dipping stamp 600 may be moved toward the target substrate 400 so that the devices 500, on which the adhesive material 300 is dipped, are positioned on the corresponding device bonding parts 401 of the target substrate 400, respectively. At this time, the target substrate 400 may be heated using various heating processes, such as halogen lamps, infrared heating, resistance heating, arc heating, induction heating, dielectric heating, electron beam heating, and the like. As an example, the infrared heating may include a process of irradiating an IR laser. At this time, the target substrate 400 may be heated to, for example, 80° C. to 100° C.

The target substrate 400 may include the device bonding parts 401 and the substrate base part 402.

Each of the device bonding parts 401 may be a thin-film metal including one or more of chromium (Cr), titanium (Ti), molybdenum (Mo), aluminum (Al), gold (Au), copper (Cu), nickel (Ni), or may include a solder composed of an alloy selected from metals or non-metals such as tin (Sn), silver (Ag), copper (Cu), lead (Pb), bismuth (Bi), indium (In), cadmium (Cd), antimony (Sb), gallium (Ga), arsenic (As), germanium (Ge), zinc (Zn), aluminum (Al), gold (Au), silicon (Si), nickel (Ni), phosphorus (P), and a combination thereof.

The substrate base part 402 may be one of a backplane, a PCB, or an integrated circuit, but the present invention is not limited thereto. For example, when the substrate base part 402 includes a backplane, the backplane may be one of a TFT backplane, a CMOS backplane, an LTPS backplane, and an a-Si backplane, but the present invention is not limited thereto.

In order to facilitate the transfer of the dipped adhesive material 300 to the target substrate 400, a surface treatment process including oxygen plasma and ultraviolet ray treatment may be performed on the target substrate 400 before performing the process illustrated in FIG. 5D. When the surface treatment process is performed on the target substrate 400, the adhesive material 300 may be applied (transferred) more effectively on the target substrate 400.

Next, as shown in FIG. 5E, after bringing the second dipping stamp 600 into contact with the target substrate 400, the adhesive material 300 may be activated to form electrical and physical connections between the devices 500 and the device bonding parts 401. That is, after bringing (attaching) the second dipping stamp 600 into contact with the target substrate 400, one or more external forces, such as heat, laser, and pressure, may be applied to activate the dipped adhesive material 300 on the target substrate 400. Then, electrical and physical connections may be formed between the devices 500 and the device bonding parts 401 by the activated adhesive material 300.

Next, as shown in FIG. 5F, the dipped adhesive material 300 may be cooled to room temperature, and then, the interposer 601 may be separated from the device 500, thereby finally transferring (applying or dipping) and bonding the device 500 to the target substrate 400. At this time, the adhesive material 300 may be cooled using various cooling sources such as nitrogen or coolant liquid.

In some embodiments of the present invention, the process of FIGS. 5A-5F may be performed without heating to a certain temperature T, depending on the properties of the adhesive material (e.g., viscosity).

Meanwhile, in the embodiment of the present invention, as shown in FIG. 5D, it is described that, in a state in which the target substrate 400 is heated, the second dipping stamp 600 is moved toward the target substrate 400 so that the devices 500, on which the adhesive material 300 is dipped, are disposed on the corresponding device bonding parts 401 of the target substrate 400, respectively. However, as shown in FIG. 5E, when heat is applied to the target substrate 400, or the adhesive material 300 and its surroundings are irradiated with a laser to activate the adhesive material 300, the second dipping stamp 600 may be moved toward the target substrate 400 so that the devices 500, on which the adhesive material 300 is dipped, are disposed on the corresponding device bonding parts 401 of the target substrate 400, respectively, without heating the target substrate 400, as shown in FIG. 5D.

Meanwhile, any composition in the form of a film or paste with a viscosity of 10⁵ Pa·s or more at room temperature (25° C.) and a viscosity of 10⁴ Pa's or less at a high temperature of 80° C. or higher may be used as the adhesive material 200 according to the embodiment of the present invention.

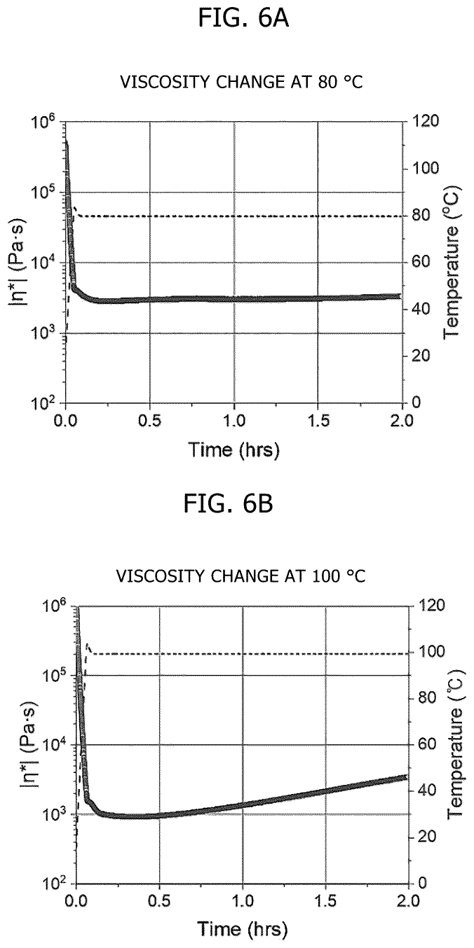

FIGS. 6A and 6B are graphs illustrating experimental results of viscosity changes over heating time for an underfill film, which is one of the adhesive materials according to one embodiment of the present invention.

Referring to FIGS. 6A and 6B, it can be seen that the viscosity of the adhesive material 200 drops to less than one-tenth of its original value almost instantly from the start of heating, reaches its minimum viscosity, and then gradually increases over time.

Accordingly, in order to reproducibly control the viscosity of the adhesive material 300 in the process according to the embodiment of the present invention, rapid heating and cooling of the adhesive material 200 are essential.

Thus, in the process according to the embodiment of the present invention, either a halogen lamp or an infrared laser may be used as a heat source to rapidly increase the temperature of the adhesive material 200, but the present invention is not limited thereto. In addition, nitrogen or coolant liquid may be used as a cooling source for rapid cooling of the adhesive material 200, but the present invention is not limited thereto.

When the adhesive material 200 is not hardened or hardly hardened by rapid temperature increase using either a halogen lamp or an infrared laser, the dipped adhesive material 300 applied on the target substrate 400 according to the embodiment of the present invention can be used in a tiling process. In this case, the term “hardly hardened” may mean, for example, a hardening degree of 0.2 or less.

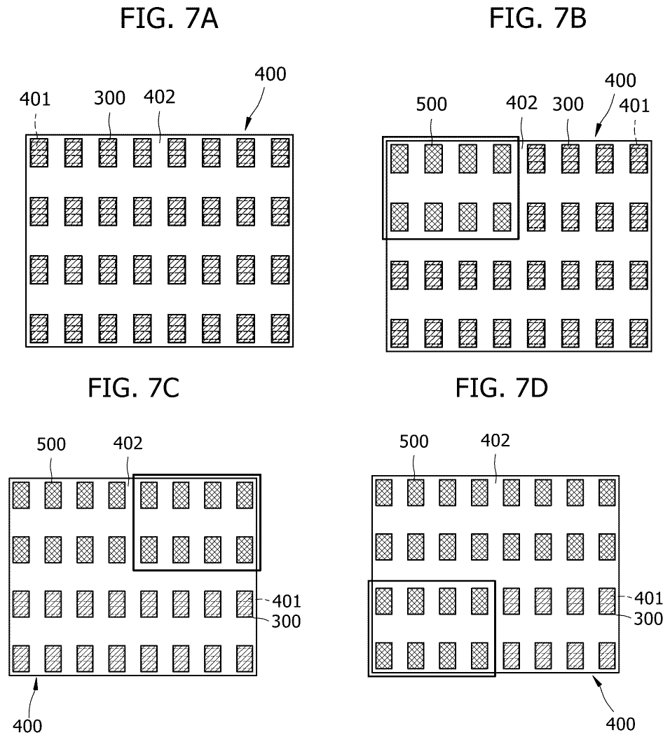

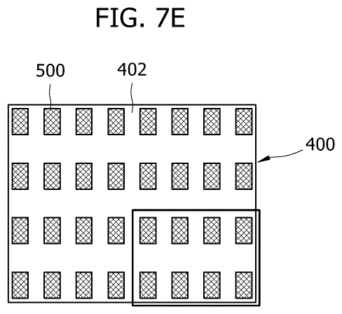

FIGS. 7A to 7E are views for describing a tiling process according to one embodiment of the present invention.

First, as shown in FIG. 7A, the dipped adhesive material 300 may be applied on the target substrate 400, which includes the device bonding parts 401 and the substrate base part 402. At this time, the dipped adhesive material 300 may be applied on the target substrate 400 using the adhesive material application method described with reference to FIGS. 2A to 2G and 4.

Next, as shown in FIG. 7B, the devices 500 may be transferred to some of the device bonding parts 401 using various transfer processes. For example, the devices 500 may be transferred using transfer processes such as laser-induced forward transfer, electrostatic transfer, fluidic-based assembly transfer, elastomer stamp transfer, roll-to-roll (R2R) transfer, vacuum suction force-based transfer, electromagnetic transfer, and the like.

The devices 500 transferred to some of the device bonding parts 401 through various transfer processes may be subjected to one or more external forces, such as heat, laser, and pressure. The dipped adhesive material 300 may be activated by such external forces, and electrical and physical connections may be formed between the devices 500 and the device bonding parts 401 by the activated adhesive material 300.

Next, as shown in FIGS. 7C, 7D, and 7E, the devices 500 may be repeatedly transferred and bonded to the device bonding parts 401, on which the devices 500 have not been transferred, to transfer and bond the devices 500 to the target substrate 400.

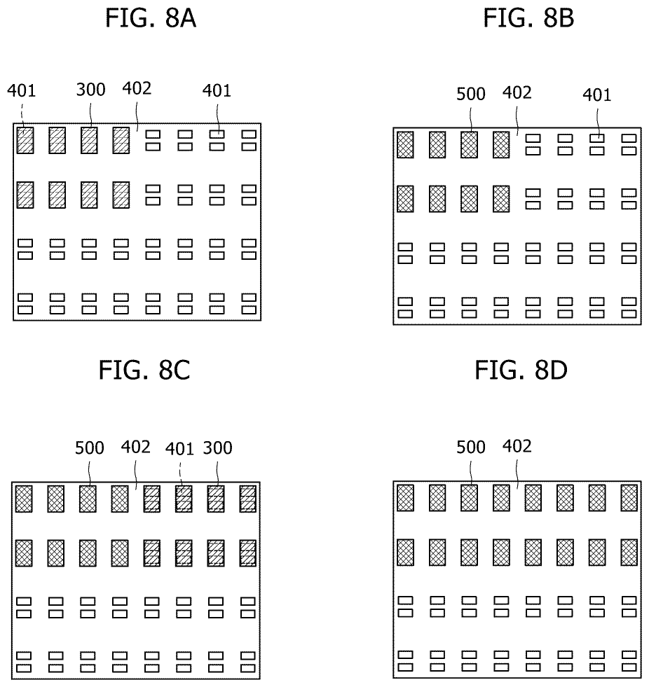

FIGS. 8A to 8D are views for describing a tiling process according to another embodiment of the present invention.

First, as shown in FIG. 8A, the dipped adhesive material 300 may be applied on some device bonding parts 401 of the target substrate 400. At this time, the dipped adhesive material 300 may be applied on the target substrate 400 using the adhesive material application method described with reference to FIGS. 2A to 2G and 4.

Next, as shown in FIG. 8B, the devices 500 may be transferred to the device bonding parts 401, on which the adhesive material 300 is applied, using various transfer processes. For example, the devices 500 may be transferred using transfer processes such as laser-induced forward transfer, electrostatic transfer, fluidic-based assembly transfer, elastomer stamp transfer, roll-to-roll (R2R) transfer, vacuum suction force-based transfer, electromagnetic transfer, and the like.

The devices 500 transferred to some of the device bonding parts 401 through various transfer processes may be subjected to one or more external forces, such as heat, laser, and pressure. The dipped adhesive material 300 may be activated by such external forces, and electrical and physical connections may be formed between the devices 500 and the device bonding parts 401 by the activated adhesive material 300.

Next, as shown in FIGS. 8C and 8D, on the device bonding parts 401, on which the devices 500 have not been transferred, the adhesive material 200 may be repeatedly applied and the devices 500 may be repeatedly transferred and bonded to transfer and bond the devices 500 to the entire target substrate 400.

Next, on the device bonding parts 401, on which the devices 500 have not been transferred, the adhesive material 200 may be repeatedly applied and the devices 500 may be repeatedly transferred and bonded to transfer and bond the devices 500 to the entire target substrate 400.

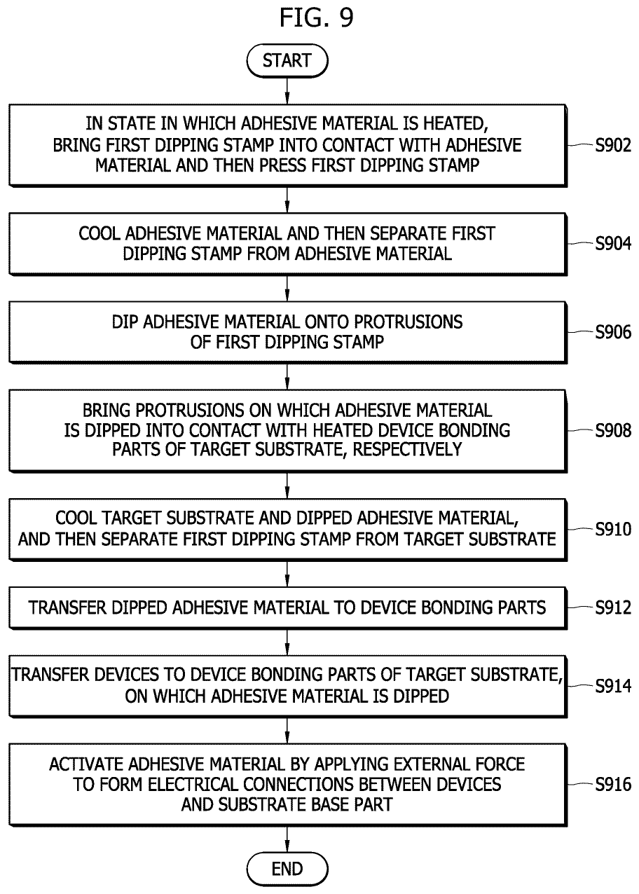

FIG. 9 is a flowchart for describing a method for dipping an adhesive material using the first dipping stamp according to one embodiment of the present invention.

Referring to FIG. 9, in a state in which the adhesive material 200 is heated, the first dipping stamp 100 is brought into contact with the adhesive material 200 and then pressed (S902).

After performing operation S902, the adhesive material 200 is cooled and then the first dipping stamp 100 is separated from the adhesive material 200 (S904).

When operation S904 is performed, the adhesive material 300 is dipped onto the protrusions 103 of the first dipping stamp 100 (S906). That is, when the adhesive material 200 is cooled and the first dipping stamp 100 is separated therefrom, the adhesive material 300 may be dipped onto the protrusions 103 of the first dipping stamp 100.

After performing operation S906, in a state in which the target substrate 400 is heated, the protrusions 103 of the first dipping stamp 100, on which the adhesive material 300 is dipped, are brought into contact with the corresponding device bonding parts 401 of the target substrate 400, respectively (S908).

That is, in a state in which the target substrate 400 is heated through a heating process, the first dipping stamp 100 may be moved toward the target substrate 400 so that the protrusions 103, on which the adhesive material 300 is dipped, are disposed on the corresponding device bonding parts 401 of the target substrate 400, respectively.

Thereafter, the first dipping stamp 100 may be brought into contact with the target substrate 400. At this time, the target substrate 400 may be in a heated state.

Accordingly, when the first dipping stamp 100 is brought into contact with (attached to) the heated target substrate 400, the adhesive material 300 dipped onto the dipping stamp 100 may flow down and be dipped (applied) onto the target substrate 400.

After performing operation S908, when the target substrate 400 and the dipped adhesive material 300 are cooled, and then the first dipping stamp 100 is separated from the target substrate 400 (S910), and the dipped adhesive material 300 is transferred to the device bonding parts 401 of the target substrate 400 (S912). That is, when the first dipping stamp 100 is separated from the target substrate 400, the dipped adhesive material 300 may be transferred (dipped or applied) to the device bonding parts 401.

When operation S912 is performed, the devices 500 are transferred to the device bonding parts 401 of the target substrate 400, on which the adhesive material 300 is dipped, using a transfer process (S914).

When operation S914 is performed, the dipped adhesive material 300 is activated to electrically and physically connect the devices 500 to the device bonding parts 401, thereby electrically connecting the devices 500 to the substrate base part 402 (S916).

That is, when one or more external forces, such as heat, laser, and pressure, are applied, the adhesive material 300 dipped onto the target substrate 400 is activated, and the devices 500 transferred to the target substrate 400 may form electrical and physical connections with the device bonding parts 401 through the activated adhesive material 300. Then, the devices 500 may be electrically connected to the substrate base part 402 of the target substrate 400.

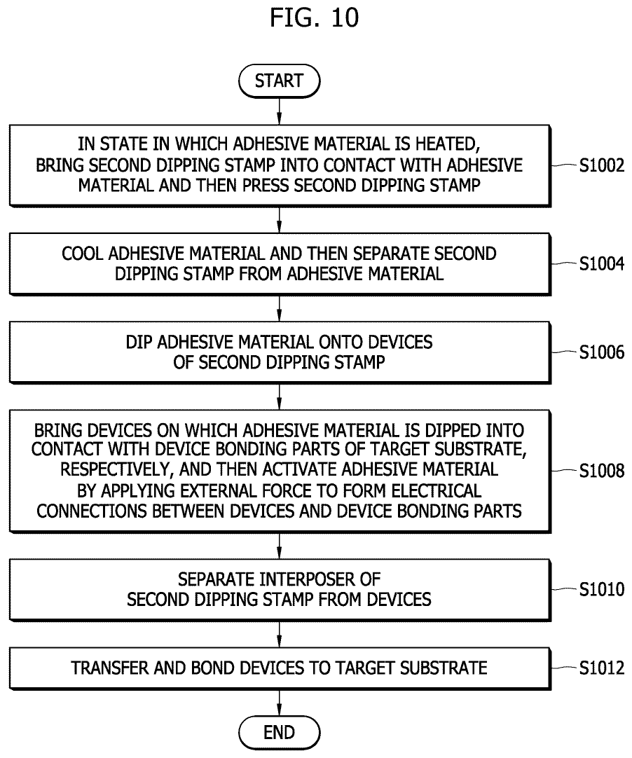

FIG. 10 is a flowchart for describing a method for dipping an adhesive material using the second dipping stamp according to one embodiment of the present invention.

Referring to FIG. 10, in a state in which the adhesive material is heated, the second dipping stamp 600 is brought into contact with the adhesive material 200 and then pressed (S1002).

After performing operation S1002, the adhesive material 200 is cooled and then the second dipping stamp 600 is separated from the adhesive material 200 (S1004).

When operation S1004 is performed, the adhesive material 300 is dipped onto the devices 500 of the second dipping stamp 600 (S1006). That is, when the adhesive material 200 is cooled and the second dipping stamp 600 is separated therefrom, the adhesive material 300 may be dipped onto the devices 500 of the second dipping stamp 600.

After performing operation S1006, in a state in which the target substrate 400 is heated, the second dipping stamp 600 is brought into contact with the target substrate 400, and then the adhesive material 300 is activated to form electrical and physical connections between the devices 500 and the device bonding parts 401 (S1008).

That is, in a state in which the target substrate 400 is heated, the second dipping stamp 600 may be moved toward the target substrate 400 so that the devices 500, on which the dipped adhesive material 300 is dipped, are positioned on the corresponding device bonding parts 401 of the target substrate 400, respectively.

At this time, the target substrate 400 may not be heated. That is, when heat is applied to the target substrate 400, or the adhesive material 300 and its surroundings are irradiated with a laser in order to activate the adhesive material 300, the target substrate 400 may not be heated. Thereafter, the second dipping stamp 600 may be brought into contact with (attached to) the heated target substrate 400, and one or more external forces, such as heat, laser, and pressure, may be applied to activate the dipped adhesive material 300 on the target substrate 400. Then, electrical and physical connections may be formed between the devices 500 and the device bonding parts 401 by the activated adhesive material 300.

When operation S1008 is performed, the interposer 601 of the second dipping stamp 600 is separated from the device 500 (S1010).

When operation S1010 is performed, the devices 500 are transferred and bonded to the target substrate 400 (S1012).

As described above, according to one aspect of the present invention, the present invention has an effect of improving the yield and speed of transfer, bonding, and repair processes of semiconductor devices including MLCCs, CMOS chips, ASICs, HBMs, SoCs, and the like and display devices including micro LEDs, mini LEDs, and the like by using a stamp for dipping an adhesive material to selectively apply the adhesive material with a high resolution of several tens of μm and at a high speed within seconds.

Further, according to one aspect of the present invention, the present invention can contribute to high integration and productivity improvement of displays, wearable devices, artificial intelligence semiconductors, system semiconductors, quantum computing devices, optical communication modules, and the like by presenting a new process for implementing selective application of an adhesive material with a high resolution of several tens of μm and at a high processing speed.

Further, according to one aspect of the present invention, the present invention allows only devices to be bonded to be selectively transferred and bonded to a target substrate regardless of the arrangement of devices disposed on a transfer substrate or mother substrate, by forming protrusions 103 (or devices) on a dipping stamp to match the arrangement of a device array to be bonded on the target substrate and selectively applying the adhesive material to only a desired position on the target substrate with a resolution of several tens of μm. Furthermore, the present invention enables simplification of an interposer manufacturing process in the manufacturing of micro LED displays, and high integration of chiplet-based heterogeneous bonding in the packaging of semiconductors.

Further, according to one aspect of the present invention, when it is necessary to repair defective devices, a dipping stamp capable of applying an adhesive material at the level of a single device can be produced and used multiple times to selectively apply the adhesive material only to regions in need of repair on a target substrate, this eliminates the need to produce a new repair interposer to match the arrangement of defective devices each time a repair is needed. This simplifies the complex processes of conventional device repair technologies and significantly reduces processing time, which can greatly enhance the productivity of micro LED display manufacturing and chiplet heterogeneous bonding.

According to one aspect of the present invention, the present invention has an effect of improving the yield and speed of transfer, bonding, and repair processes of semiconductor devices including MLCCs, CMOS chips, ASICs, HBMs, SoCs, and the like and display devices including micro LEDs, mini LEDs, and the like by using a stamp for dipping an adhesive material to selectively apply the adhesive material with a high resolution of tens of μm and at a high speed within seconds.

Further, according to one aspect of the present invention, the present invention can contribute to the high integration and productivity improvement of displays, wearable devices, artificial intelligence semiconductors, system semiconductors, quantum computing devices, optical communication modules, and the like by presenting a new process for implementing selective application of an adhesive material with a high resolution of several tens of μm and at a high processing speed.

Further, according to one aspect of the present invention, the present invention allows only devices to be bonded to be transferred and bonded to a target substrate regardless of the arrangement of devices disposed on a transfer substrate or mother substrate, by forming protrusions (or devices) on a dipping stamp to match the arrangement of a device array to be bonded on the target substrate and selectively applying the adhesive material to only a desired position on the target substrate with a resolution of several tens of μm. Furthermore, the present invention enables simplification of an interposer manufacturing process in the manufacturing of micro LED displays, and high integration of chiplet-based heterogeneous bonding in the packaging of semiconductors.

Further, according to one aspect of the present invention, when it is necessary to repair defective devices, a dipping stamp capable of applying an adhesive material at the level of a single device can be produced and used multiple times to selectively apply the adhesive material only to regions in need of repair on a target substrate, this eliminates the need to produce a new repair interposer to match the arrangement of defective devices each time a repair is needed. This simplifies the complex processes of conventional device repair technologies and significantly reduces processing time, which can greatly enhance the productivity of micro LED display manufacturing and chiplet heterogeneous bonding.

The present invention has been described above with reference to the embodiments illustrated in the drawings, but the description is merely illustrative, and one of ordinary skill in the art to which the art pertains should understand that various modifications and other equivalent embodiments are possible from the description above.

Accordingly, the scope of the present invention shall be determined only according to the attached claims.

What is claimed is:

1. A method for dipping an adhesive material, the method comprising:
dipping an adhesive material onto a first dipping stamp;
transferring the adhesive material, which is dipped onto the first dipping stamp, to a target substrate; and
transferring a device to the target substrate, to which the adhesive material is transferred.

2. The method of claim 1, wherein the first dipping stamp includes:
a base part; and
a concave-convex part provided on the base part,
wherein the concave-convex part includes one or more protrusions.

3. The method of claim 1, wherein the adhesive material is in the form of a film or paste and is made of at least one of a curable resin, a reducing agent, a thermoplastic resin, a curing agent, and a solder.

4. The method of claim 1, wherein the dipping of the adhesive material includes:
bringing the first dipping stamp into contact with the adhesive material in a state in which the adhesive material is heated, and then pressing the first dipping stamp;
cooling the adhesive material and then separating the first dipping stamp from the adhesive material; and
dipping the adhesive material onto protrusions of the first dipping stamp.

5. The method of claim 4, wherein a shape and volume of the adhesive material dipped onto the first dipping stamp are determined by at least one of a surface state, a heating temperature, and an applied pressure of the protrusions of the first dipping stamp and the adhesive material.

6. The method of claim 4, further comprising, after the dipping of the adhesive material onto the protrusions of the first dipping stamp, forming the separated adhesive material into a flat film or paste by heating or blading.

7. The method of claim 1, wherein the target substrate includes:
a substrate base part; and
one or more device bonding parts disposed on an upper surface of the substrate base part.

8. The method of claim 7, wherein the transferring of the dipped adhesive material to the target substrate includes:
bringing protrusions of the first dipping stamp, on which the adhesive material is dipped, into contact with the corresponding device bonding parts of the target substrate, respectively, in a state in which the target substrate is heated;
cooling the dipped adhesive material and the target substrate and then separating the first dipping stamp from the target substrate; and
transferring the dipped adhesive material to the device bonding parts.

9. The method of claim 8, further comprising, before the bringing of the protrusions of the first dipping stamp, on which the adhesive material is dipped, into contact with the corresponding device bonding parts of the target substrate, respectively, performing a surface treatment process on the target substrate.

10. The method of claim 1, wherein the transferring of the device to the target substrate includes:
transferring the device to the device bonding part of the target substrate, on which the adhesive material is dipped, using a transfer process; and
electrically connecting the device to the substrate base part of the target substrate by activating the dipped adhesive material to electrically and physically connect the device to the device bonding part.

11. A method for dipping an adhesive material, the method comprising:
dipping an adhesive material onto a second dipping stamp having one or more devices provided thereon; and
transferring and bonding the one or more devices to a target substrate through the adhesive material dipped onto the second dipping stamp.

12. The method of claim 11, wherein the second dipping stamp includes:
an interposer; and
one or more devices provided on the interposer,
wherein the interposer is a substrate formed of at least one of Si, glass, quartz, and a polymer film, with an adhesive layer formed in a film form or as a pattern array.

13. The method of claim 11, wherein the adhesive material is in the form of a film or paste and is made of at least one of a curable resin, a reducing agent, a thermoplastic resin, a curing agent, and a solder.

14. The method of claim 11, wherein the dipping of the adhesive material includes:
bringing the second dipping stamp into contact with the adhesive material in a state in which the adhesive material is heated, and then pressing the second dipping stamp;
cooling the adhesive material and then separating the second dipping stamp from the adhesive material; and
dipping the adhesive material onto the devices of the second dipping stamp.

15. The method of claim 14, wherein a shape and volume of the adhesive material dipped onto the second dipping stamp are determined by at least one of a surface state, a heating temperature, and an applied pressure of the devices of the second dipping stamp and the adhesive material.

16. The method of claim 14, further comprising, after the dipping of the adhesive material onto the devices of the second dipping stamp, forming the separated adhesive material into a flat film or paste by heating or blading.

17. The method of claim 11, wherein the target substrate includes:
a substrate base part; and
one or more device bonding parts disposed on an upper surface of the substrate base part.

18. The method of claim 11, wherein the transferring and bonding of the one or more devices to the target substrate includes:
bringing the devices of the second dipping stamp, on which the adhesive material is dipped, into contact with the corresponding device bonding parts of the target substrate, respectively, and then activating the dipped adhesive material to form electrical and physical connections between the devices and the device bonding parts; and
transferring and bonding the devices to the target substrate by separating an interposer of the second dipping stamp from the devices.

19. The method of claim 18, wherein, in the forming of the electrical and physical connections between the devices and the device bonding parts, the second dipping stamp is moved toward the target substrate and brought into contact with the target substrate so that the devices, on which the adhesive material is dipped, are disposed on the corresponding device bonding parts of the target substrate, respectively, an external force is applied to activate the dipped adhesive material, and the devices and the device bonding parts are electrically and physically connected by the activated adhesive material.

20. The method of claim 18, further comprising, before the bringing of the devices of the second dipping stamp, on which the adhesive material is dipped, into contact with the corresponding device bonding parts of the target substrate, respectively, performing a surface treatment process on the target substrate.
